(19) United States
(12) Patent Application Publication
(10) Pub. No.: US 2003/0034565 A1
(43) Pub. Date: Feb. 20, 2003

(54) Flip chip substrate with metal columns

(76) Inventors: James Jaen-Don Lan, Fremont, CA (US); Chien Wei Chang, Taoyuan (TW)

Correspondence Address: Bo-In Lin, 13445 Mandoli Drive, Los Altos Hills, CA, 94022, US

(21) Appl. No.: 10/224,285

(22) Filed: Aug. 19, 2002

Related U.S. Application Data
(60) Provisional application No. 60/313,551, filed on Aug. 18, 2001.

(51) Int. Cl. H01L 23/48

(52) U.S. Cl. 257/778

(57) ABSTRACT

The present invention discloses a flip-chip package assembly. The flip-chip package assembly includes a flipped IC chip having a plurality of input/output terminals mounted onto a substrate wherein the substrate includes a plurality of conductive columns disposed on top the substrate with each of the conductive columns disposed at a location corresponding to a location of one of the input/output terminals on the IC chip. The substrate further includes a layer of low-modulus polymer layer disposed on top of the substrate surrounding and bonding to the conductive columns to flexibly yield to bending of the conductive columns.

This Application claims a Priority Filing Date of Aug. 18, 2001 benefited from a previously filed Application No. 60/313,551 by the same Applicants.

### BACKGROUND OF THE INVENTION

1. Field of the Invention

This invention relates generally to the electronic package. More particularly, this invention relates to a novel technique fabricate a laminated plastic substrate for packaging a flip chip assembly by employing special metal columns to improve package integrity and reliability.

2. Description of the Prior Art

The problems of package reliability and excessive stress caused by mismatches between the coefficients of temperature expansion (CTE) are still a technical challenge to those of ordinary skill in the art for making electronic packages, particularly, packages of flip chip assemblies. The current substrate used in flip-chip assembly has an array of receiving pads attached to the surface of the substrate. The silicon die, i.e., an integrated circuit (IC) chip, is flipped upside down with solder bumps landing on the receiving pads with each of the solder bumps formed on the circuit-supporting surface of the chip mounted onto a pre-applied solder paste. The assembly will then be processed through high temperature to reflow the solder and form an intermetalic joint between the silicon pad and the substrate pad as that shown in FIG. 1A. The process will go through cycles of temperature elevation and cooling down. The metal joint is solidified while it cooled down below the eutectic point. The stress will then start to build up at the metal joint while the assembly continues to cool down to the room temperature due to the mismatched coefficient of temperature expansion (CTE) of silicon (˜3 ppm/° C.) and laminated substrate (˜18 ppm/° C.). The epoxy liquid is then applied at the peripheral of die to fill up the gap between silicon and substrate. This underfill epoxy is employed to bond the silicon to the substrate so that the stress induced will not damage the metal joint, instead, it will be transferred down to the substrate and create warpage on the substrate as well as the silicon chip. As that shown in FIG. 1B, in the existing flip-chip PBGA assembly, the modulus of underfill material is designed around 4000-5000 MPa to be higher than that of substrate material (˜2900 Mpa for BT). Therefore the thermal mechanical stress generated from solder reflow temperature cycle will cause the silicon edges as well as the underneath substrate to bend downward and form a convex warpage. The thermal and mechanical stresses as shown can cause silicon and/or solder joint reliability problem. This issue has been well documented in many publications and patents. Some of the prior art patents and publications are U.S. Pat. No. 4,067,104 by J. M. Tracy, 1978, U.S. Pat. No. 4,642,889 by D. G. Grabbe, 1987, U.S. Pat. No. 5,381,848 by R. T. Trabucco, 1995, U.S. Pat. No. 5,470,787 by S. E. Greer, 1995, U.S. Pat. No. 5,497,938 by J. F. McMahon and G. Chiu, 1996, U.S. Pat. No. 5,773,889 by D. G. Love, 1998, U.S. Pat. No. 6,177,636 by J. C. Fjelstad, 2001, U.S. Pat. No. 6,215,670 by I. Y. Khandros, 2001, U.S. Pat. No. 6,049,976 by I. Y. Khandros, 2000, U.S. Pat. No. 6,255,599 by C. S. Chang, 2001, U.S. Pat. No. 5,959,348 by C. S. Chang, 1999 and IEEE Publication on CHMT, 12(4), pp. 566-570 by N. Matsui et. al., 1987. Most of solutions disclosed in the prior arts are applied on the silicon chip as part of the wafer bumping process such as: Rockwell's Layered Solder Column, AMP's Solder Column, NTT's Stacked-Sphere Technology, Motorola's Solder Post, Fujitsu's Wire Interconnect, FormFactor's Wire Skeleton Solder Column and Spring Technology, Tessera's Etched Copper Post. FIGS. 1C and 1D show the flip-chip assemblies with solder column bumped chip and copper posts as disclosed in these related art disclosures. However, those processes have not been widely commercialized due to the process cost and yield issue.

The current flip-chip assembly is using underfill epoxy with high modulus to bond the chip to the substrate. Although it provides strong bonding between silicon chip and substrate, the induced stress has hence been transferred down to the solder joint between the package substrate and PCB. While the solder joint of package to PCB comprises a larger diameter of solder ball which can acts like the spring and absorb certain level of stress. It works for silicon chip up to certain size and has to limit the use in mild environment. However, with increasing demand of larger silicon chip, the stress can go beyond the elastic point of solder and the warpage of silicon induced from the stress will becomes more significant. It can cause fatigue at solder joint as well as silicon crack or create stress-induced malfunction. As mentioned in the discovery of prior arts, most of solutions are applied on silicon. They have both cost and yield issues. This is one of the reasons why the flip-chip technology has not widely used for the package with large chips.

As of now, the functionality of an IC chip has been continuously expanded due to the needs of higher electrical performance and more complicate application. Therefore, the number of transistors in an IC chip has, so far, outgrown the reduction of transistor geometry. It has resulted a larger IC chip size such as microprocessor, FPGA, graphic chip, PC chipset, network processor, etc. In addition, the push of wafer fabrication technology to smaller photo geometry and multiple metal layers has made the IC chip more sensitive to the effect of the mechanical stress. It can alter or even damage the functionality of the IC chip. Therefore, the demand for a new and improved configuration to resolve current technical limitations and difficulties become even more pronounced.

Therefore, a need still exits in the art to provide an improved configuration and procedure for carrying out packaging of integrated circuit (IC) chips with significant reduced stress at the metal joints between the silicon and the substrate while maintaining mechanical stability with lower production cost and higher yields.

### SUMMARY OF THE PRESENT INVENTION

It is therefore an object of the present invention to provide a new configuration and method for packaging the flip chip assemblies to significantly reduce the stress caused by the mismatches between the CTEs in order to overcome the aforementioned difficulties encountered in the prior art.

Specifically, it is an object of the present invention to provide a new configuration and processes for manufacturing the laminated substrate for packaging flip-chip assemblies. This invention utilize the mature PCB copper plating process, commercially available low stress polymer and laser drill process which is widely used for PBGA substrate fabrication for different purpose of forming small and shallow via hole. The product produced by this invention can be cost effective and can solve the stress-related issue in the IC flip-chip assembly.

Briefly, in a preferred embodiment, the present invention applies a new manufacturing process by forming an array of metal (copper or solder) columns on the substrate in contrast to solder columns formed on the IC as used by the prior art. The copper columns are applied to absorb the stress induced from the metal joint between silicon and substrate. The copper columns are further embedded in a layer of low modulus polymer. The low modulus polymer functions as bonding epoxy allows the copper column to bend to yield to the stress induced from the CTE mismatch while it still provide certain bonding to the silicon and provide mechanical stability through the underfill epoxy. According to this invention, the cooper or solder columns are formed directly on the substrate not the silicon. It provides solution for the stress relief with lower cost and higher packaging yield.

In a different preferred embodiment, this invention applies a new manufacturing process by forming an array of metal (copper or solder) columns on the substrate. The copper columns are applied to absorb the stress induced from the metal joint between silicon and substrate. The copper columns are further embedded in a layer of dielectric layer which is mechanically cut with slotted gaps of dielectric blocks surrounding the cooper/solder columns. The dielectric layer formed with slotted gaps surrounding the cooper/solder columns provide space for allowing deformation of the columns in yielding to the stress induced from the CTE mismatch while it still provide certain bonding to the silicon and provide mechanical stability through the underfill epoxy. Again, the cooper or solder columns are formed directly on the substrate not the silicon. It provides solution for the stress relief with lower cost and higher packaging yield.

This invention further provides a substrate fabrication technology to form an array of copper (or solder) columns. The columns are formed with the height in the range of 3-12 mils which are surrounded by a layer of low modulus polymer about half or less of the modulus of substrate material to receive the solder bumps of a silicon chip.

These and other objects and advantages of the present invention will no doubt become obvious to those of ordinary skill in the art after having read the following detailed description of the preferred embodiment which is illustrated in the various drawing figures.

### BRIEF DESCRIPTION OF THE DRAWINGS

FIG. 1A is the cross sectional views of flip-chip assembly with existing substrate laminate;

FIG. 1B is the cross section view of a flip-chip assembly with convex chip and substrate warpage caused by stresses due to CTE mismatches;

FIG. 1C is the cross section view of a prior art flip-chip assembly with solder column bumped chip;

FIG. 1D is the cross section of a prior art flip-chip assembly with pre-attached copper post;

FIG. 2A is a cross sectional view of a flip-chip assembly with substrate of this invention:

FIG. 2B is a cross sectional view of another flip-chip assembly with substrate of the extension of this invention—Copper Column Stack;

FIG. 2C shows a cross sectional view of a Flip-Chip PBGA Assembly with copper column substrate of this invention;

FIG. 3A shows top view of a flip chip BGA substrate with copper column of this invention;

FIG. 3B shows cross section view of a flip chip BGA substrate with copper column of this invention;

FIG. 3C shows top view of a flip chip BGA substrate with copper column supported by slotted dielectric;

FIG. 3D shows cross section view of a flip chip BGA substrate with copper columns supported by slotted dielectric;

FIGS. 4A to 4I are a series of cross sectional view for showing the processing steps employed by a PCB substrate manufacturing process;

FIGS. 5A and 5B are cross sectional views for showing the processing steps implemented to create slots around the column; and

FIGS. 6A and 6B are cross sectional views of the flip-chip packages according to two preferred embodiments of this invention for showing deformation of the cooper columns to absorb and relieve the stresses.

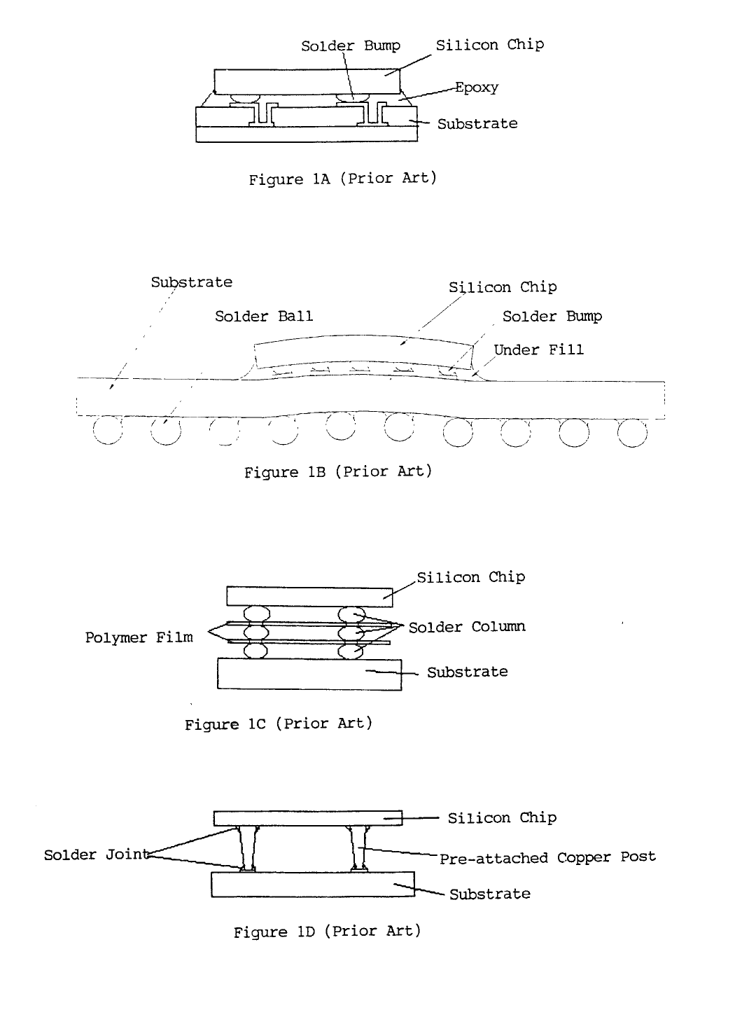

### DETAILED DESCRIPTION OF THE PREFERRED EMBODIMENT

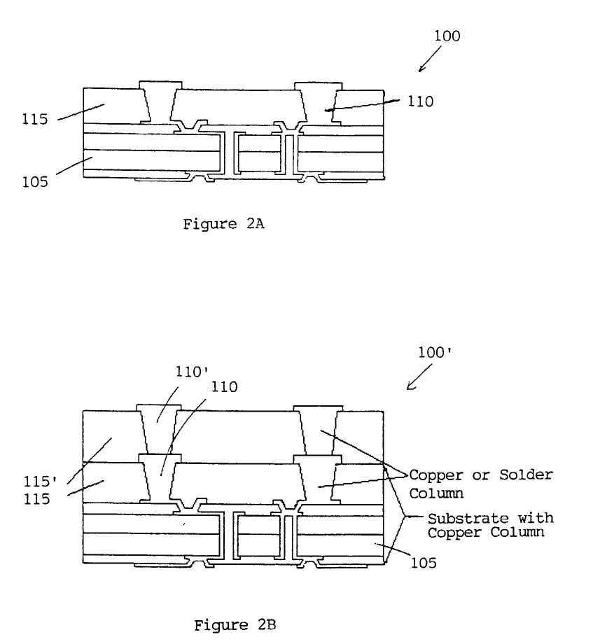

FIG. 2A is a cross sectional view of a flip-chip packaging substrate 100 of this invention. The flip chip substrate package is supported on a multiple-layered supporting substrate 105 with via connectors to interconnect the conductive traces on the upper surface of the supporting substrate to the lower surface of the supporting substrate 105. The packaging substrate 100 further includes a plurality of cooper or solder-columns 110 embedded in a layer of low modulus polymer 115. FIG. 2B is a cross sectional view of another packaging substrate 100′ that further includes a second sets of cooper or solder-columns 110′ stacked on top of the first set of cooper or solder columns 110. The second set of the cooper or solder-columns 110′ are embedded in a second layer of low modulus polymer 115′ formed on top of the first polymer layer 115. According to specific processes to be further described below, the packaging substrate manufactured with process from this invention comprises an array of metal columns (copper or solder) 110 or 110′ with height in the range of 3-12 mils. These cooper or solder columns are embedded in a layer of low modulus polymer with modulus less than half for that of substrate material modulus. FIG. 2C shows a flip-chip 120 mounted on to the packaging substrate 100 with solder balls 125 mounted onto the cooper or solder column 110. The space between the solder balls 125 above the low modulus polymer layer 115 is filled with underfill 130. A second set of solder balls 135 is formed on the bottom of the via-connectors for external connections.

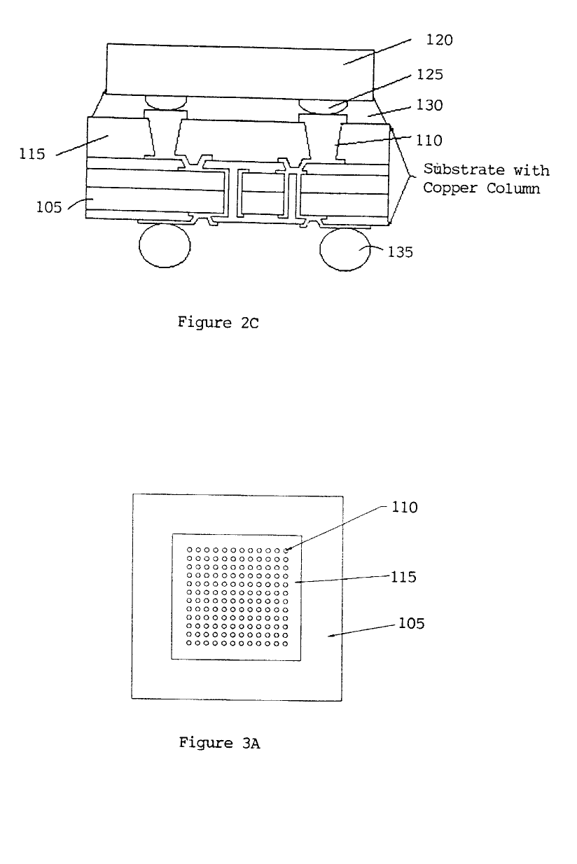

FIGS. 3A and 3B are a top view and side cross sectional view respectively of the PBGA substrate of this invention. The PBGA substrate is supported on a laminated multi-layered supporting substrate 105 supports a plurality of cooper or solder columns 110 embedded and surrounded by a low modulus polymer layer 115. FIGS. 3C and 3D are a top view and side cross sectional view respectively of another PBGA substrate as another preferred embodiment of this invention. The PBGA substrate 200 is supported on a laminated multi-layered supporting substrate 205 supports a plurality of cooper or solder columns 210 embedded and surrounded by a dielectric layer 215 that has a similar modulus as the supporting substrate 105. A laser drill process is applied to cut the dielectric layer as a plurality of blocks separating from a neighboring blocks with slots 240 having a gap larger than two mills. The slots are provided for allowing space to reduce the stress caused by deformation of the cooper columns.

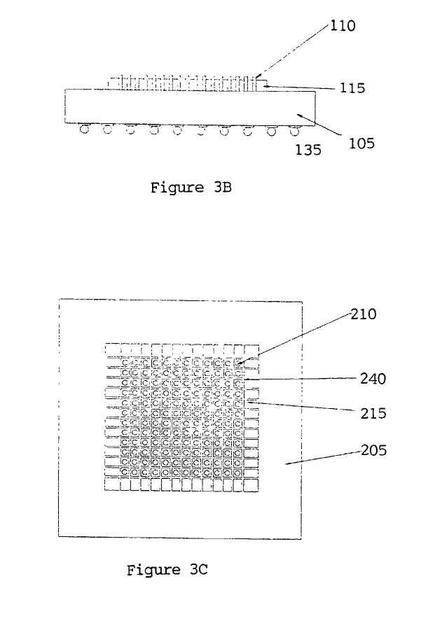

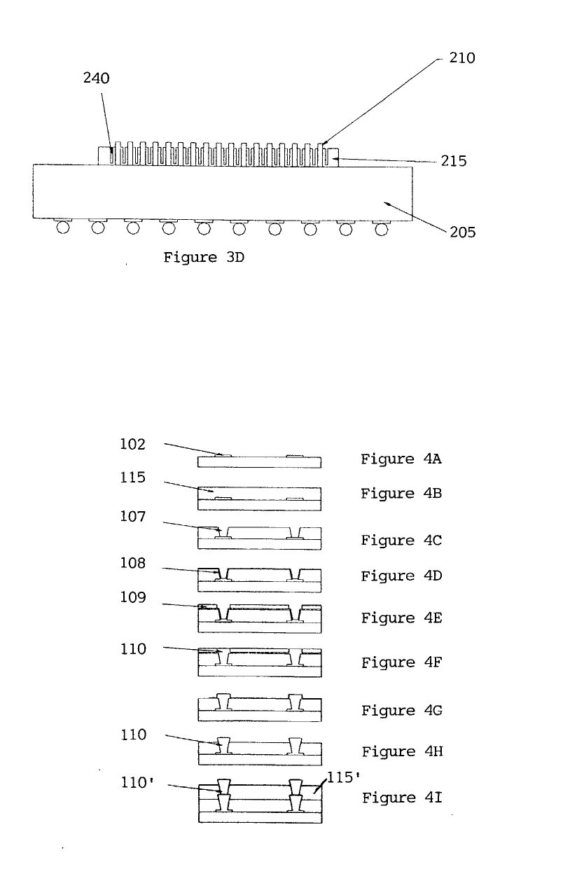

FIGS. 4A to 4I are a series of cross sectional views for shown the manufacturing process for producing the packaging substrate according to the disclosures of this invention. In FIG. 4A, cooper pads 102 are deposited on the top surface of the supporting substrate 105. In FIG. 4B, a layer of low modulus polymer 115 is formed on top of the supporting substrate 105 covering the cooper pads 102. In FIG. 4C, a laser drill is carried out on the layer of the low modulus polymer 115 to open a plurality of holes 107 thus exposing the cooper pads 102. In FIG. 4D, a cooper flashing/plating layer 108 is formed over the top surface. In FIG. 4E, a photo-resist layer 109 is formed over the entire top surface except the opening holes 107. In FIG. 4F, a cooper plating is carried out to fill the opening holes 107 with cooper columns 110. In FIG. 4G, the photo resist layer 109 is removed and in FIG. 4H, the cooper flashing/plating layer 107 is stripped thus exposing the cooper columns 110. In FIG. 5I, the above steps are repeated for form a stacked cooper columns 110′ embedded in another layer of low modulus polymer 115′.

FIGS. 5A and 5B are cross sectional view of another embodiment of this invention. The packaging substrate 200 formed on a supporting substrate 205, is provided with a plurality of cooper or solder-columns 210. The cooper-columns or solder-columns are surrounded with slotted dielectric layer 215 formed by similar material of the supporting substrate 105. The dielectric layer is mechanically cut with slots 240 to allow spaces for reducing stress caused by deformation of the cooper-columns or the solder columns 210. FIG. 5B is a cross sectional view where the cooper-columns or solder columns are formed as stacked columns and the dielectric layers are stacked with the slotted gaps 240′ separating the dielectric block surrounding each cooper or solder columns.

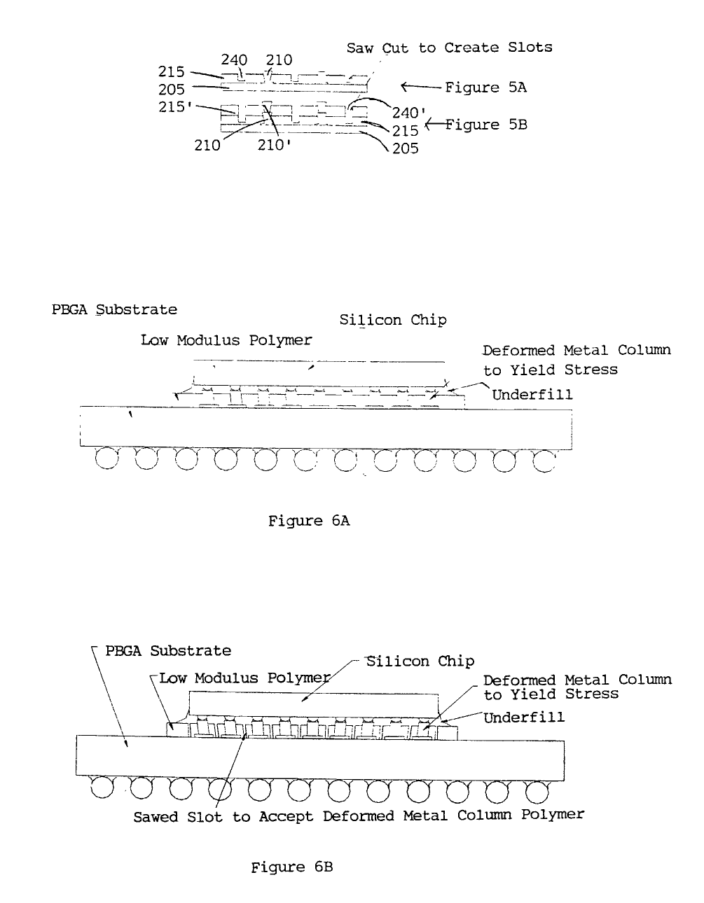

FIGS. 6A and 6B are two different cross sectional views for showing the configurations of a flip-chip package after the package is processed with the temperature cycles. As shown in FIGS. 6A and 6B, the cooper or solder columns are deformed and tilted as the results of mismatches of the CTE between the substrate and the IC chip. The low modulus polymer layer 110 or the slotted dielectric layer 210 provide flexibility for the cooper or solder columns to yield to the stress and settle to a deform position. The limitations caused by reliability difficulties due to the stress at several joints induced by temperature cycles are now significantly reduced.

This invention discloses a substrate provided for mounting an integrated circuit (IC) chip thereon. The substrate includes a plurality of conductive columns disposed on top the substrate. The substrate further includes a stress-yield layer disposed on top of the substrate surrounding and bonding to the conductive columns provided to flexibly yield to bending of the conductive columns. In a preferred embodiment, this invention discloses an electronic package. The electronic package includes an IC chip mounted onto a substrate wherein the substrate includes a plurality of conductive columns disposed on top the substrate. The substrate further includes a stress-yield layer disposed on top of the substrate surrounding and bonding to the conductive columns provided to flexibly yield to bending of the conductive columns.

This invention further discloses a method for manufacturing a substrate provided for mounting an integrated circuit (IC) chip thereon. The method includes steps of disposing a plurality of conductive columns on top the substrate. The method further includes a step of disposing a stress-yield layer on top of the substrate surrounding and bonding to the conductive columns provided to flexibly yield to bending of the conductive columns. In a preferred embodiment, the method of disposing a stress-yield layer on top of the substrate surrounding and bonding to the conductive columns is a step of disposing a low-modulus polymer layer on the top surface of the substrate. In another preferred embodiment, the method of disposing a stress-yield layer on top of the substrate surrounding and bonding to the conductive columns is a step of disposing a dielectric layer and cutting the dielectric layer with a plurality slotted gaps for separating an area surrounding each of the conductive columns to flexibly yield to bending of the conductive columns. This invention further discloses a method for packaging an IC chip. The method includes steps of disposing a plurality of conductive columns on top the substrate. The method further includes steps of disposing a stress-yield layer on top of the substrate surrounding and bonding to the conductive columns provided to flexibly yield to bending of the conductive columns. The method further includes a step of mounting the IC chip on top of the substrate. In a preferred embodiment, the method of disposing a stress-yield layer on top of the substrate surrounding and bonding to the conductive columns is a step of disposing a low-modulus polymer layer on the top surface of the substrate. In another preferred embodiment, the method of disposing a stress-yield layer on top of the substrate surrounding and bonding to the conductive columns is a step of disposing a dielectric layer and cutting the dielectric layer with a plurality slotted gaps for separating an area surrounding each of the conductive columns to flexibly yield to bending of the conductive columns.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A substrate provided for mounting an integrated circuit (IC) chip thereon, wherein said IC chip having a plurality of input/output terminals, said substrate comprising:
a plurality of conductive columns disposed on top said substrate with each of said conductive columns disposed at a location corresponding to a location of one of said input/output terminals on said integrated circuit chip; and
a layer of low-modulus polymer layer disposed on top of said substrate surrounding and bonding to said conductive columns to flexibly yield to bending of said conductive columns.

2. The substrate of claim 1 wherein:
said plurality of conductive columns are a plurality of cooper columns.

3. The substrate of claim 1 wherein:
said plurality of conductive columns are a plurality of solder columns.

4. The substrate of claim 1 further comprising:
a plurality of conductive pads, each of said pads is disposed on top of said substrate beneath said conductive columns for providing conductive contacts on said substrate.

5. The substrate of claim 4 wherein:
said substrate further includes conductive traces connected to said conductive pads for electrically connecting to said conductive columns.

6. The substrate of claim 5 wherein:
said substrate further includes via connector includes via conductors disposed in via-holes penetrating said substrate wherein said conductive traces are further connected to said via connectors for electrically connecting to said conductive pads and said conductive columns.

7. The substrate of claim 6 further comprising:
a plurality of solder balls constituting a ball grid array (BGA) disposed on a bottom surface of said substrate and electrically connected to said via-connectors for electrically connecting to said conductive pads and said conductive columns.

8. The substrate of claim 1 further comprising:
a plurality of stacked conductive columns each disposed on top said conductive columns supported by said substrate;
a stacked layer of low-modulus polymer layer disposed on top of said layer of low modulus polymer supported on said substrate for surrounding and bonding to said stacked conductive columns to flexibly yield to bending of said stacked conductive columns.

9. A flip-chip package assembly:
a flipped IC chip having a plurality of input/output terminals mounted onto a substrate wherein said substrate includes a plurality of conductive columns disposed on top said substrate with each of said conductive columns disposed at a location corresponding to a location of one of said input/output terminals on said IC chip; and
said substrate further includes a layer of low-modulus polymer layer disposed on top of said substrate surrounding and bonding to said conductive columns to flexibly yield to bending of said conductive columns.

10. The flip-chip package assembly of claim 9 wherein:
said plurality of conductive columns are a plurality of cooper columns.

11. The flip-chip package assembly of claim 9 wherein:
said plurality of conductive columns are a plurality of solder columns.

12. The flip-chip package assembly wherein said substrate further comprising:
a plurality of conductive pads, each of said pads is disposed on top of said substrate beneath said conductive columns for providing conductive contacts on said substrate.

13. The flip-chip assembly of claim 12 wherein:
said substrate further includes conductive traces connected to said conductive pads for electrically connecting to said conductive columns.

14. The flip-chip assembly of claim 13 wherein:
said substrate further includes via connector includes via conductors disposed in via-holes penetrating said substrate wherein said conductive traces are further connected to said via connectors for electrically connecting to said conductive pads and said conductive columns.

15. The flip-chip assembly of claim 14 further comprising:
a plurality of solder balls constituting a ball grid array (BGA) disposed on a bottom surface of said substrate and electrically connected to said via-connectors for electrically connecting to said conductive pads and said conductive columns.

16. The flip-chip assembly of claim 9 further comprising:
a plurality of stacked conductive columns each disposed on top said conductive columns supported by said substrate;
a stacked layer of low-modulus polymer layer disposed on top of said layer of low modulus polymer supported on said substrate for surrounding and bonding to said stacked conductive columns to flexibly yield to bending of said stacked conductive columns.

17. A substrate provided for mounting an integrated circuit (IC) chip thereon, wherein said IC chip having a plurality of input/output terminals, said substrate comprising:
a plurality of conductive columns disposed on top said substrate with each of said conductive columns disposed at a location corresponding to a location of one of said input/output terminals on said integrated circuit chip; and
a layer of dielectric layer disposed on top of said substrate surrounding and bonding to said conductive columns wherein said dielectric layer having a plurality of slotted gaps separating an area surrounding each of said conductive columns to flexibly yield to bending of said conductive columns.

18. The substrate of claim 17 wherein:
said plurality of conductive columns are a plurality of cooper columns.

19. The substrate of claim 17 wherein:
said plurality of conductive columns are a plurality of soder columns.

20. The substrate of claim 17 further comprising:
a plurality of conductive pads, each of said pads is disposed on top of said substrate beneath said conductive columns for providing conductive contacts on said substrate.

21. The substrate of claim 20 wherein:
said substrate further includes conductive traces connected to said conductive pads for electrically connecting to said conductive columns.

22. The substrate of claim 21 wherein:
said substrate further includes via connector includes via conductors disposed in via-holes penetrating said substrate wherein said conductive traces are further connected to said via connectors for electrically connecting to said conductive pads and said conductive columns.

23. The substrate of claim 22 further comprising:
a plurality of solder balls constituting a ball grid array (BGA) disposed on a bottom surface of said substrate and electrically connected to said via-connectors for electrically connecting to said conductive pads and said conductive columns.

24. The substrate of claim 17 further comprising:
a plurality of stacked conductive columns each disposed on top said conductive columns supported by said substrate;
a stacked dielectric layer disposed on top of said dielectric layer supported on said substrate for surrounding and bonding to said stacked conductive columns wherein said stacked dielectric layer having a plurality of slotted gaps separating an area surrounding each of said conductive columns to flexibly yield to bending of said stacked conductive columns.

25. A flip-chip package assembly:
a flipped IC chip having a plurality of input/output terminals mounted onto a substrate wherein said substrate includes a plurality of conductive columns disposed on top said substrate with each of said conductive columns disposed at a location corresponding to a location of one of said input/output terminals on said IC chip; and
said substrate further includes a layer of dielectric layer disposed on top of said substrate surrounding and bonding to said conductive columns wherein said dielectric layer having a plurality of slotted gaps separating an area surrounding each of said conductive columns to flexibly yield to bending of said conductive columns.

26. The flip-chip package assembly of claim 25 wherein:
said plurality of conductive columns are a plurality of cooper columns.

27. The flip-chip package assembly of claim 25 wherein:
said plurality of conductive columns are a plurality of solder columns.

28. The flip-chip package assembly of claim 25 wherein said substrate further comprising:
a plurality of conductive pads, each of said pads is disposed on top of said substrate beneath said conductive columns for providing conductive contacts on said substrate.

29. The flip-chip assembly of claim 28 wherein:
said substrate further includes conductive traces connected to said conductive pads for electrically connecting to said conductive columns.

30. The flip-chip assembly of claim 29 wherein:
said substrate further includes via connector includes via conductors disposed in via-holes penetrating said substrate wherein said conductive traces are further connected to said via connectors for electrically connecting to said conductive pads and said conductive columns.

31. The flip-chip assembly of claim 30 further comprising:
a plurality of solder balls constituting a ball grid array (BGA) disposed on a bottom surface of said substrate and electrically connected to said via-connectors for electrically connecting to said conductive pads and said conductive columns.

32. The flip-chip assembly of claim 9 further comprising:
a plurality of stacked conductive columns each disposed on top said conductive columns supported by said substrate;
a stacked dielectric layer disposed on top of said dielectric layer supported on said substrate for surrounding and bonding to said stacked conductive columns wherein said stacked dielectric layer having a plurality of slotted gaps separating an area surrounding each of said conductive columns to flexibly yield to bending of said stacked conductive columns.

33. A substrate provided for mounting an integrated circuit (IC) chip thereon comprising:
a plurality of conductive columns disposed on top said substrate; and
a stress-yield layer disposed on top of said substrate surrounding and bonding to said conductive columns provided to flexibly yield to bending of said conductive columns.

34. A electronic package comprising:
an IC chip mounted onto a substrate wherein said substrate includes a plurality of conductive columns disposed on top said substrate; and
said substrate further includes a stress-yield layer disposed on top of said substrate surrounding and bonding to said conductive columns provided to flexibly yield to bending of said conductive columns.

35. A method for manufacturing a substrate provided for mounting an integrated circuit (IC) chip thereon comprising:
disposing a plurality of conductive columns on top said substrate; and
disposing a stress-yield layer on top of said substrate surrounding and bonding to said conductive columns provided to flexibly yield to bending of said conductive columns.

36. The method of claim 35 wherein:
said method of disposing a stress-yield layer on top of said substrate surrounding and bonding to said conductive columns is a step of disposing a low-modulus polymer layer on said top surface of said substrate.

37. The method of claim 34 wherein:
said method of disposing a stress-yield layer on top of said substrate surrounding and bonding to said conductive columns is a step of disposing a dielectric layer and cutting said dielectric layer with a plurality slotted gaps for separating an area surrounding each of said conductive columns to flexibly yield to bending of said conductive columns.

38. A method for packaging an IC chip comprising:
disposing a plurality of conductive columns on top said substrate;
disposing a stress-yield layer on top of said substrate surrounding and bonding to said conductive columns provided to flexibly yield to bending of said conductive columns; and
mounting said IC chip on top of said substrate.

39. The method of claim 38 wherein:
said method of disposing a stress-yield layer on top of said substrate surrounding and bonding to said conductive columns is a step of disposing a low-modulus polymer layer on said top surface of said substrate.

40. The method of claim 38 wherein:
said method of disposing a stress-yield layer on top of said substrate surrounding and bonding to said conductive columns is a step of disposing a dielectric layer and cutting said dielectric layer with a plurality slotted gaps for separating an area surrounding each of said conductive columns to flexibly yield to bending of said conductive columns.
